(19) United States
(12) Patent Application Publication
(10) Pub. No.: US 2025/0149519 A1
(43) Pub. Date: May 8, 2025

(54) SEMICONDUCTOR PACKAGE

(71) Applicant: Samsung Electronics Co., Ltd., Suwon-si (KR)

(72) Inventors: Hyunsoo Chung, Suwon-si (KR); Jinchan Ahn, Suwon-si (KR); Chiwoo Lee, Suwon-si (KR)

(21) Appl. No.: 18/769,823

(22) Filed: Jul. 11, 2024

(30) Foreign Application Priority Data
Nov. 7, 2023 (KR) 10-2023-0153105

(51) Int. Cl. H01L 25/16; H01L 23/00; H01L 23/31; H01L 23/367; H10B 80/00

(52) U.S. Cl. CPC H01L 25/167; H01L 23/3107; H01L 23/367; H01L 24/16; H01L 25/165; H10B 80/00; H01L 2224/16227; H01L 2224/16238; H01L 2924/1431; H01L 2924/1436

(57) ABSTRACT

A semiconductor package includes a package substrate, a plurality of stacked structures on the package substrate, each stacked structure including a plurality of core chips stacked on each other, each core chip including a memory cell array including a plurality of memory cells, a buffer chip on the package substrate, and spaced apart from the plurality of stacked structures in a horizontal direction, and a photonics package including an optical integrated circuit chip on the package substrate, an electronic integrated circuit chip on the optical integrated circuit chip, and a first molding layer surrounding side surfaces of the electronic integrated circuit chip, wherein the buffer chip is configured to control the memory cell of the core chip of each of the plurality of stacked structures.

### CROSS-REFERENCE TO RELATED APPLICATION

This application is based on and claims priority under 35 U.S.C. § 119 to Korean Patent Application No. 10-2023-0153105, filed on Nov. 7, 2023 in the Korean Intellectual Property office, the disclosure of which is incorporated by reference herein in its entirety.

### BACKGROUND

Aspects of the inventive concept relate to a semiconductor package and a manufacturing method of the semiconductor package, and more particularly, to a semiconductor package including an optical integrated circuit chip.

For functional improvement and integration of constituent components of electronic devices, advantages of semiconductor packages are utilized in many cases. Semiconductor packages enable various integrated circuits, such as memory chips or logic chips, to be mounted on a package substrate. Recently, in an environment where data traffic is growing in data centers and communication infrastructure, research on semiconductor packages containing optical integrated circuits continues.

### SUMMARY

Aspects of the inventive concept provide a semiconductor package including a buffer chip with improved efficiency.

Aspects of the inventive concept provide a semiconductor package having good heat management.

In addition, the issues to be addressed by the technical idea of the inventive concept are not limited to those mentioned above and below, and other issues may be clearly understood by those of ordinary skill in the art from the following descriptions.

According to an aspect of the inventive concept, a semiconductor package includes a package substrate, a plurality of stacked structures on the package substrate, each stacked structure including a plurality of core chips stacked on each other, each core chip including a memory cell array including a plurality of memory cells, a buffer chip on the package substrate, and spaced apart from the plurality of stacked structures in a horizontal direction, and a photonics package including an optical integrated circuit chip on the package substrate, an electronic integrated circuit chip on the optical integrated circuit chip, and a first molding layer surrounding side surfaces of the electronic integrated circuit chip, wherein the buffer chip is configured to control the memory cell of the core chip of each of the plurality of stacked structures.

According to another aspect of the inventive concept, a semiconductor package includes a package substrate, a plurality of stacked structures on the package substrate, each stacked structure including a plurality of core chips stacked on each other, each core chip including a memory cell array including a plurality of memory cells, a buffer chip on the package substrate, and spaced apart from the plurality of stacked structures in a horizontal direction, and an optical integrated circuit chip on the package substrate, an electronic integrated circuit chip on the optical integrated circuit chip, and a first molding layer surrounding side surfaces of the electronic integrated circuit chip, wherein the buffer chip is configured to control the memory cells of the core chips of each of the plurality of stacked structures, wherein the total number of buffer chips on the package substrate is less than the total number of stacked structures including the plurality of core chips stacked on each other on the package substrate, and wherein the plurality of stacked structures and the optical integrated circuit chip are arranged to surround side surfaces of the buffer chip.

According to another according to another aspect of the inventive concept, a semiconductor package includes a package substrate, a plurality of stacked structures on the package substrate, each stacked structure including a plurality of core chips stacked on each other, each core chip including dynamic random access memory (RAM) (DRAM) memory cells, a buffer chip on the package substrate and spaced apart from the plurality of stacked structures, a photonics package including an optical integrated circuit chip on the package substrate, an electronic integrated circuit chip on the optical integrated circuit chip, and a first molding layer surrounding side surfaces of the electronic integrated circuit chip, and a second molding layer on the package substrate, and surrounding side surfaces of the plurality of stacked structures, the buffer chip, and the photonics package, wherein the buffer chip is configured to control the memory cells of the core chips of each of the plurality of stacked structures, wherein the plurality of stacked structures and the photonics package are arranged to surround side surfaces of the buffer chip, and wherein the first molding layer of the photonics package includes an opening portion extending from an upper surface of the first molding layer inward.

### BRIEF DESCRIPTION OF THE DRAWINGS

Embodiments will be more clearly understood from the following detailed description taken in conjunction with the accompanying drawings in which:

FIG. 1 is a schematic plan view of a semiconductor package according to an embodiment;

FIG. 2 is a schematic cross-sectional view of a semiconductor chip of FIG. 1, taken along line A-A′ in FIG. 1;

FIG. 3 is an enlarged cross-sectional view of region EX1 of a semiconductor package of FIG. 2;

FIG. 4 is a schematic enlarged cross-sectional view of a portion of a semiconductor package, according to an embodiment.

FIG. 5 is a schematic cross-sectional view of a semiconductor package, according to an embodiment;

FIG. 6 is a schematic cross-sectional view of a semiconductor package, according to an embodiment;

FIG. 7 is a schematic plan view of a semiconductor package according to an embodiment; and

FIGS. 8 through 11 are diagrams illustrating a manufacturing method of a semiconductor package, according to embodiments.

### DETAILED DESCRIPTION OF THE EMBODIMENTS

Because various changes can be applied to the embodiments and accordingly, the embodiments can have various types, some embodiments are illustrated in the drawings and detailed descriptions thereof are provided. However, the various changes are not intended to limit the embodiments to particular disclosure forms.

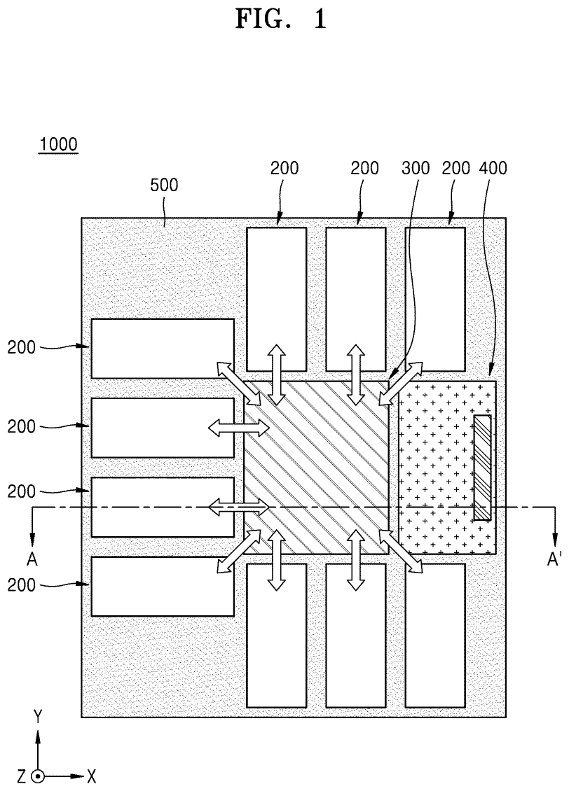

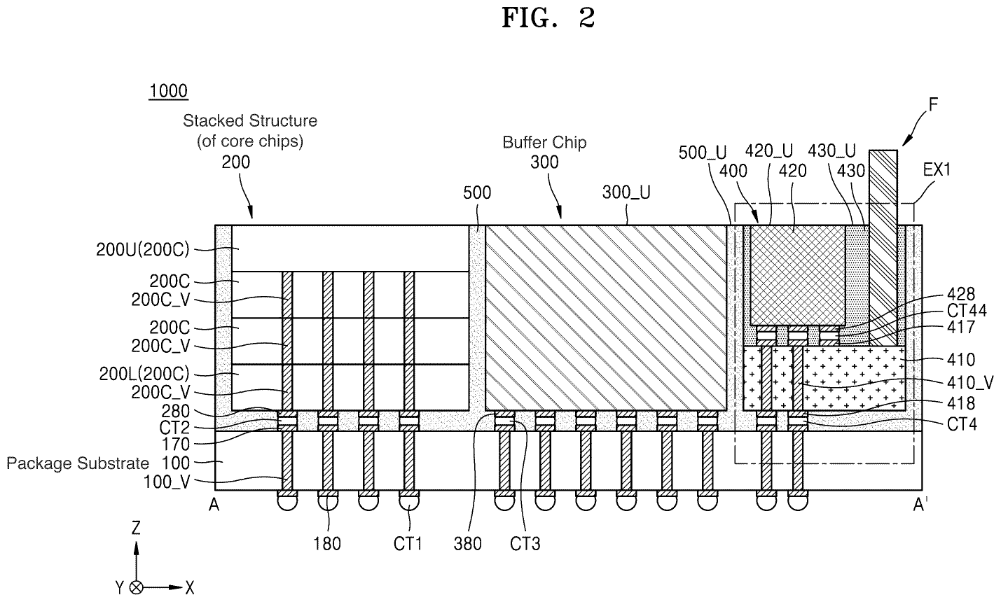

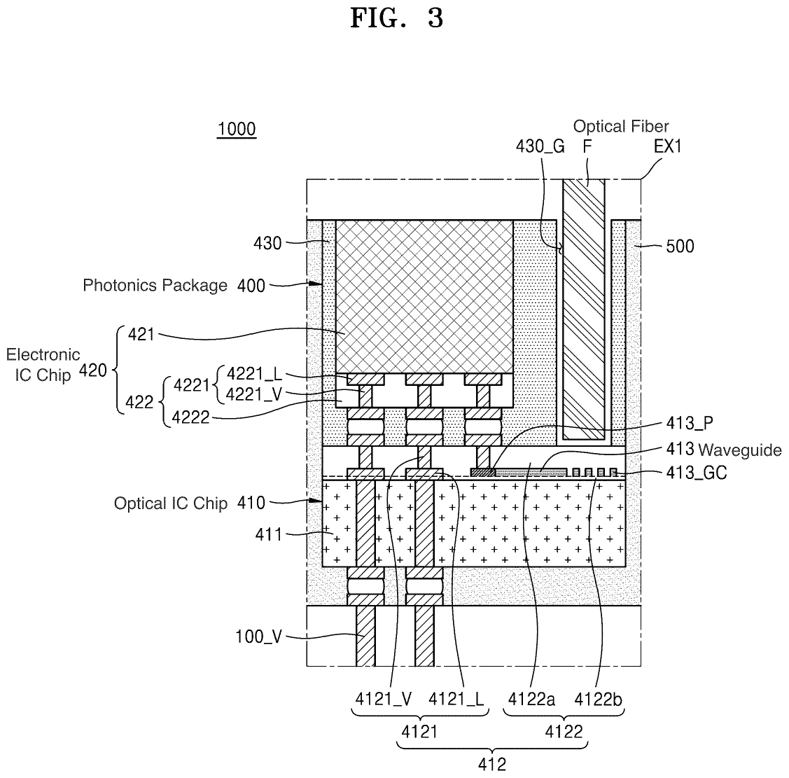

FIG. 1 is a schematic plan view of a semiconductor package 1000 according to an embodiment. FIG. 2 is a schematic cross-sectional view of the semiconductor package 1000 of FIG. 1, taken along line A-A′ in FIG. 1. FIG. 3 is an enlarged cross-sectional view of region EX1 of the semiconductor package 1000 of FIG. 2.

Referring to FIGS. 1 through 3, the semiconductor package 1000 may include a package substrate 100, a plurality of stacked structures 200, a buffer chip 300, a photonics package 400. In the semiconductor package 1000, the number of stacked structures 200 may be greater than the number of buffer chips 300.

Hereinafter, unless otherwise defined, a direction in parallel to an upper surface of the package substrate 100 may be defined as a first horizontal direction (X direction), a direction perpendicular to the upper surface of the package substrate 100 may be defined as a vertical direction (Z direction), and a direction perpendicular to the first horizontal direction (X direction) and the vertical direction (Z direction) may be defined as a second horizontal direction (Y direction). A direction, in which the first horizontal direction (X direction) and the second horizontal direction (Y direction) are combined, may be defined as a horizontal direction. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The package substrate 100 may be an interposer including a substrate and a plurality of through vias 100_V penetrating the substrate. For example, the package substrate 100 may include a glass interposer, in which the substrate includes glass, and the through vias 100_V include a plurality of through glass vias (TGV). However, the embodiments are not limited thereto, and the package substrate 100 may include a silicon interposer in which the substrate includes silicon and the through vias 100_V includes silicon through vias (TSV). Generally speaking, vias that pass through a substrate may be described herein as through substrate vias.

In some embodiments, the package substrate 100 may include or be a redistribution structure, the redistribution structure including a redistribution pattern and a redistribution insulating layer surrounding the redistribution pattern.

The redistribution insulating layer may include or be formed of an insulating material, for example, photo imageable dielectric (PID) resin. In some embodiments, the redistribution insulating layer may also further include an inorganic filler. In some embodiments, the redistribution insulating layer may have a multi-layer structure in which the redistribution pattern is arranged on each layer.

The redistribution pattern may include at least one redistribution line pattern extending in the horizontal direction and at least one redistribution via pattern extending in the vertical direction (Z direction) from the redistribution line pattern. The redistribution line pattern at each vertical level may include a plurality of conductive lines extending in one or more horizontal directions. The redistribution via pattern at each vertical level may include a plurality of conductive vias extending vertically through an insulating layer, each conductive via connecting to a respective line above it and/or a respective line below it. A redistribution line pattern may be arranged on at least one of an upper surface and a lower surface of a respective redistribution insulating layer or inside a respective redistribution insulating layer. For example, each conductive line of a redistribution line pattern may be formed in one insulating layer at the same vertical level as the conductive line, and on (for example directly on) another insulating layer below the conducive line. The redistribution via patterns may penetrate the redistribution insulating layers and be connected to the redistribution line patterns.

The redistribution pattern may include or be formed of a conductive material, for example, copper (Cu), aluminum (Al), silver (Ag), tin (Sn), gold (Au), nickel (Ni), lead (Pb), titanium (Ti), or an alloy thereof. For example, the conductive via and conductive lines of the redistribution pattern may include or be formed of a conductive material, for example, copper (Cu), aluminum (Al), silver (Ag), tin (Sn), gold (Au), nickel (Ni), lead (Pb), titanium (Ti), or an alloy thereof. Different portions of a redistribution pattern may be formed of the same materials or of different materials.

In some embodiments, the package substrate 100 may include or be a printed circuit board (PCB) including a core insulating layer including or formed of at least one material selected from phenol resin, epoxy resin, and polyimide.

The package substrate 100 may include upper pads 170 on an upper surface thereof andlower pads 180 on a lower surface thereof. Respective pairs of the upper pads 170 and the lower pads 180 may be connected to each other via a through via 100_V. However, the embodiments are not limited thereto, and respective upper pads 170 and lower pads 180 may be electrically connected to each other via a redistribution pattern or an internal wiring. In some embodiments, the upper pads 170 and the lower pads 180 may each include or be formed of one or more of Cu, Ni, stainless steel, or beryllium copper.

External connection terminals CT1 may be attached to the lower pad 180. The external connection terminals CT1 may be configured to electrically and physically connect between the package substrate 100 and an external device on which the package substrate 100 is mounted. The external connection terminals CT1 may be, for example, solder balls or solder bumps.

However, the embodiments are not limited thereto, and the package substrate 100 may be mounted in a socket formed in an external device. For example, in some embodiments, the package substrate 100 may be electrically and physically connected to an external device without the external connection terminals CT1.

The plurality of stacked structures 200 may be arranged on the package substrate 100. The plurality of stacked structures 200 may be apart from each other in the horizontal direction. For example, the plurality of stacked structures 200 may be arranged to surround at least part of the buffer chip 300. In some embodiments, a first set of stacked structures 200 is arranged along a first side surface of the buffer chip, a second set of stacked structures 200 is arranged along a second side surface of the buffer chip, and a third set of stacked structures 200 is arranged along a third side surface of the buffer chip.

Each of the plurality of stacked structures 200 may include a plurality of core chips 200C stacked in the vertical direction (Z direction). Each of the plurality of core chips 200C may include a memory cell array including a plurality of memory cells. For example, each of the plurality of core chips 200C may be a type of memory semiconductor chip.

In some embodiments, the plurality of core chips 200C may include memory semiconductor chips of the same type. For example, the plurality of core chips 200C may all be dynamic random access memory (RAM) DRAM memory semiconductor chips.

Each of the plurality of core chips 200C may include or be formed a semiconductor material, for example, silicon (Si) or germanium (Ge). Alternatively, each of the plurality of core chips 200C may include or be formed of a compound semiconductor material, such as silicon carbide (SiC), gallium arsenide (GaAs), indium arsenide (InAs), and indium phosphate (InP).

Each of the plurality of core chips 200C may include an active surface and an inactive surface opposite the active surface. A semiconductor device including a plurality of individual devices of various types may be formed on the active surface of each of the plurality of core chips 200C. Each of the plurality of core chips 200C may include a conductive region or a well doped with impurities. Each of the plurality of core chips 200C may have various device isolation structures such as a shallow trench isolation (STI) structure.

The plurality of individual devices on the active surface of each of the plurality of core chips 200C may be electrically connected to the conductive region. For example, each of the plurality of core chips 200C may further include a conductive wiring or conductive plugs electrically connecting the plurality of individual devices to the conductive region. In addition, each of the plurality of individual devices may be electrically isolated from another adjacent individual device by an insulating layer.

Each of the plurality of core chips 200C may include or be a memory semiconductor chip including a memory cell array. For example, a memory semiconductor chip may be a non-volatile memory device, such as flash memory, phase change random access memory (RAM) (PRAM), magnetoresistive RAM (MRAM), ferroelectric RAM (FeRAM), or resistive RAM (RRAM). In some embodiments, the semiconductor chip may be a volatile memory device, such as DRAM or static RAM (SRAM).

In some embodiments, a core chip 200C at the uppermost end among the plurality of core chips 200C may be referred to as an uppermost end core chip 200U, and a core chip 200C at the lowermost end among the plurality of core chips 200C may be referred to as a lowermost end core chip 200L. In FIG. 2, each of the plurality of stacked structures 200 is illustrated as including four core chips stacked, but the number of core chips 200C included in each of the plurality of stacked structures 200 is not limited thereto.

In some embodiments, lower pads 280 may be on a lower surface of the lowermost end core chip 200L. The lower pads 280 of the lowermost end core chip 200L may be electrically connected to respective through vias 200C_V or a conductive region.

The lower pads 280 of the lowermost end core chip 200L may be electrically connected to the upper pads 170 of the package substrate 100, respectively, via respective connection terminals CT2. Connection terminals CT2 (as well as connection terminals CT3, CT4, and CT44 described below) may be conductive terminals, such as conductive bumps or conductive pillars. However, the embodiments are not limited thereto, and the lower pads 280 of the lowermost end core chip 200L may be electrically connected to the upper pads 170 of the package substrate 100 by using an anisotropic conductive film (ACF), a non-conductive film (NCF), direct bonding, or hybrid bonding.

In some embodiments, a semiconductor chip except for the uppermost end core chip 200U among the plurality of core chips 200C may further include the through vias 200C_V, which extend from the upper surface to the inside of the semiconductor chip. The through vias 200C_V of each of the plurality of core chips 200C may be electrically connected to the conductive region of each core chip 200C. However, the embodiments are not limited to those described above, and the uppermost end core chip 200U may include the through vias 200C_V.

Each of the plurality of core chips 200C may be electrically connected to the core chip(s) 200C adjacent thereto via the through vias 200C_V. Accordingly, the plurality of core chips 200C, and each individual core chip 200C thereof, may be electrically connected to the package substrate 100 via the through vias 200C_V. For example, the conductive region of the uppermost end core chip 200U may be electrically connected to the package substrate 100 via the through vias 200C_V of the semiconductor chips stacked directly under the conductive region.

In some embodiments, a thickness of each of the plurality of core chips 200C, for example, a length thereof in the vertical direction (Z direction), may be about 20 μm to about 80 μm. The thicknesses of each chip of the plurality of core chips 200C may have substantially the same values as other chips of the plurality of core chips 200C.

In some embodiments, each of the plurality of stacked structures 200 may further include a stacked dummy chip (not illustrated). The stacked dummy chip may be at the uppermost end of each of the plurality of stacked structures 200. The stacked dummy chip may be stacked on the uppermost end core chip 200U. The stacked dummy chip may include a semiconductor material, for example, Si. In some embodiments, the stacked dummy chip may include only the semiconductor material. For example, the stacked dummy chip may include a portion of a bare wafer, without any semiconductor devices formed thereon or therein.

The buffer chip 300 may be on the package substrate 100. The buffer chip 300 may be arranged apart from each stacked structure 200 of the plurality of stacked structures 200 in the horizontal direction. In some embodiments, a vertical level of a lower surface of the buffer chip 300 (e.g., a height of the lower surface above an upper surface of the package substrate 100 in the vertical direction (Z direction)) is the same as a vertical level of a lower surface of each of the plurality of stacked structures 200. In the various embodiments described herein, the vertical level may refer to a separation distance from the upper surface of the package substrate 100, or a separation distance from the lower surface of the package substrate 100.

The buffer chip 300 may be electrically connected to the plurality of stacked structures 200. The buffer chip 300 may be electrically connected to all of the plurality of stacked structures 200 via the package substrate 100. For example, lower pads 380 of the buffer chip 300 may be electrically connected to the upper pads 170 of the package substrate 100 via connection terminals CT3 (e.g., conductive terminals such as conductive bumps or conductive pillars). However, a method of electrically connecting the buffer chip 300 to the package substrate 100 is not limited thereto.

The buffer chip 300 may include a serial-parallel conversion circuit, and control the plurality of stacked structures 200. For example, the buffer chip 300 may control a memory device formed by one or more core chips 200C of each stacked structure 200. For example, the buffer chip 300 may be a high bandwidth memory (HBM) controller die, and each of the plurality of stacked structures 200 may be referred to as a DRAM stack. The buffer chip 300 may be electrically connected to each of the core chips 200C and configured to transmit commands, data, and other signals to each of the core chips 200C through the various wiring lines and vias described herein.

In some embodiments, the plurality of stacked structures 200 and the buffer chip 300 may be referred to as a shared memory module, or a compute express link (CXL) memory module. One buffer chip 300 may control all of the plurality of stacked structures 200, and then the semiconductor package 1000 may provide a memory of high capacity. The buffer chip 300 may share a memory space of the plurality of stacked structures 200, and the data processing speed of the semiconductor package 1000 may be improved.

The photonics package 400 may be over the package substrate 100. The photonics package 400 may be electrically connected to the package substrate 100. The photonics package 400 may be electrically connected to the buffer chip 300 via the package substrate 100. As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

Detailed descriptions of the photonics package 400 are provided with reference to FIG. 3.

The photonics package 400 may include an optical integrated circuit chip 410, an electronic integrated circuit chip 420, and a first molding layer 430. The photonics package 400 may convert an optical signal into an electrical signal, and may also convert an electrical signal into an optical signal. For example, the photonics package 400 may transceive an electrical signal to and from the buffer chip 300, and transceive an optical signal to and from an optical fiber F.

The optical integrated circuit chip 410 may be on the package substrate 100. For example, the optical integrated circuit chip 410 may be at the lowermost end of the photonics package 400. In some embodiments, the vertical level of a lower surface of the optical integrated circuit chip 410 may be the same as the vertical level of the lower surface of the buffer chip 300.

The optical integrated circuit chip 410 may include a first substrate 411, a first wiring structure 412, and a waveguide 413. For example, the first wiring structure 412 and the waveguide 413 may be arranged on an upper surface of the first substrate 411. The first substrate 411 may include first through vias 410_V extending from the upper surface thereof to a lower surface thereof.

In some embodiments, the first substrate 411 may include or be formed of a semiconductor material such as Si. Alternatively, the first substrate 411 may include or be formed of a semiconductor material such as Ge.

The first wiring structure 412 may include a first wiring pattern 4121 and a first insulating layer 4122 surrounding the first wiring pattern 4121. The first wiring pattern 4121 may include a plurality of first wiring lines 4121_L extending in the horizontal direction and a plurality of respective first wiring vias 4121_V extending from each respective first wiring line 4121_L in the vertical direction (Z direction). The first wiring pattern 4121 may be electrically connected to the first through vias 410_V. The term “pattern” as used herein may refer to a group of repeated components, such as vias or wiring lines, formed at the same vertical level, or may refer to an individual one of these components. As such, a first wiring pattern 4121 may refer to a plurality of first wiring lines 4121_L connected to a plurality of respective first wiring vias 4121_V, or to a single first wiring line 4121_L connected to a single first wiring via 4121_V.

The first insulating layer 4122 may be divided into a lower portion wiring insulating layer 4122b and an upper portion wiring insulating layer 4122a. In some embodiments, the lower portion wiring insulating layer 4122b may include or be formed of an oxide layer such as silicon oxide. The upper portion wiring insulating layer 4122a may include or be formed of a dielectric layer including one or more layers of silicon oxide, silicon nitride, a combination thereof, etc. In some embodiments, the lower portion wiring insulating layer 4122b and the upper portion wiring insulating layer 4122a include the same composition material.

The waveguide 413 may include or be formed of a patterned silicon layer, may be disposed on the lower portion wiring insulating layer 4122b, and may extend in the horizontal direction. For example, the waveguide 413 may be buried in the first insulating layer 4122. For example, the waveguide 413 may be on the lower portion wiring insulating layer 4122b, and may be covered by the upper portion wiring insulating layer 4122a. In some embodiments, the waveguide 413 may include or may be a silicon waveguide including silicon, and the first insulating layer 4122 may include or be a buried oxide layer. However, the embodiments are not limited thereto, and in some embodiments, the waveguide 413 may be covered by an oxide layer different from the first insulating layer 4122.

The waveguide 413 may be connected to an optical component 413_P. The optical component 413_P may convert an optical signal into an electrical signal, and may convert an electrical signal into an optical signal. In some embodiments, the optical component 413_P may include an optical detector, an optical diode, and a modulator. The waveguide 413 may include a plurality of waveguide optical lines, and the optical component 413_P may be one of a plurality of optical components 413_P, and each waveguide optical line of the waveguide may be connected to a respective optical component 413_P.

In a process of inputting an optical signal to the photonics package 400, each optical component 413_P such as an optical detector may detect an optical signal input to the optical integrated circuit chip 410. The optical integrated circuit chip 410 may detect a plurality of optical signals input via a plurality of optical detectors and convert the detected optical signals into respective electrical signals.

In a process of outputting an optical signal by the photonics package 400, the electronic integrated circuit chip 420 may transfer an electrical signal to a modulator. The modulator may input a signal corresponding to the received signal to light emitted by an optical diode, and convert the electrical signal into an optical signal. This may be performed simultaneously for a group of electrical signals and respective optical diodes.

The optical integrated circuit chip 410 may further include lower pads 418 and upper pads 417. The lower pads 418 may be under the lower surface of the first substrate 411, and may be electrically connected to the first through vias 410_V. The upper pads 417 may be on an upper surface of the first wiring structure 412, and may be electrically connected to the first wiring patterns 4121.

The lower pads 418 of the optical integrated circuit chip 410 may be electrically connected to the upper pads 170 of the package substrate 100 via connection terminals CT4. However, the embodiments are not limited thereto, and the lower pads 418 of the optical integrated circuit chip 410 may be electrically connected to the upper pads 170 of the package substrate 100 by using an ICF, an NCF, direct bonding, or hybrid bonding.

The electronic integrated circuit chip 420 may be over the optical integrated circuit chip 410. For example, the electronic integrated circuit chip 420 may overlap the first through vias 410_V of the optical integrated circuit chip 410 in the vertical direction (Z direction).

The electronic integrated circuit chip 420 may include a second substrate 421 and a second wiring structure 422. The second substrate 421 of the electronic integrated circuit chip 420 may include an active surface and an inactive surface opposite the active surface. The second wiring structure 422 may be formed on the active surface of the second substrate 421.

The second substrate 421 may include or be formed of a semiconductor material such as Si. Alternatively, the second substrate 421 may include or be formed of a semiconductor material such as Ge.

In some embodiments, the electronic integrated circuit chip 420 may include a plurality of individual devices used for interfacing with the optical integrated circuit chip 410. The plurality of individual devices of the electronic integrated circuit chip 420 may be on the active surface of the second substrate 421. For example, the electronic integrated circuit chip 420 may include complementary metal-oxide semiconductor (CMOS) drivers, trans impedance amplifiers, or the like, for performing a function of controlling high frequency signaling, or the like, of the optical integrated circuit chip 410.

The second wiring structure 422 may include a second wiring pattern 4221 and a second wiring insulating layer 4222 surrounding the second wiring pattern 4221. The second wiring pattern 4221 may include second wiring lines 4221_L extending in the horizontal direction and second wiring vias 4221_V extending from the second wiring line 4221_Lin the vertical direction (Z direction). The second wiring pattern 4221 may be electrically connected to the plurality of individual devices.

In some embodiments, the electronic integrated circuit chip 420 may be arranged on the optical integrated circuit chip 410 so that the active surface of the second substrate 421 faces the optical integrated circuit chip 410. For example, the electronic integrated circuit chip 420 may be arranged on the optical integrated circuit chip 410 in a face down manner.

The electronic integrated circuit chip 420 may further include lower pads 428. The lower pads 428 may be under the lower surface of the second wiring structure 422, and may be electrically connected to the second wiring pattern 4221.

The lower pads 428 of the electronic integrated circuit chip 420 may be electrically connected to the upper pads 417 of the optical integrated circuit chip 410 via a connection terminals CT44. However, the embodiments are not limited thereto, and the lower pads 428 of the electronic integrated circuit chip 420 may be electrically connected to the upper pads 417 of the optical integrated circuit chip 410 by using an ICF, an NCF, direct bonding, or hybrid bonding.

Electrical signals converted by the photonics package 400 may be transferred to the buffer chip 300 via the package substrate 100 and the first through vias 410_V. In some embodiments, the photonics package 400 may be electrically connected to a physical layer (PHY) of the buffer chip 300.

In some embodiments, the photonics package 400 and the plurality of stacked structures 200 may be arranged to surround the buffer chip 300. For example, the plurality of stacked structures 200 may be on a periphery region of the package substrate 100, and the buffer chip 300 and the photonics package 400 may be in the center region of the package substrate 100. For example, in some embodiments, one of side surfaces of the buffer chip 300 may face the photonics package 400, and the other side surfaces may face the plurality of stacked structures 200.

In some embodiments, the plurality of stacked structures 200 may be arranged in a U shape or a C shape. The plurality of stacked structures 200 may be arranged to surround the photonics package 400 and the buffer chip 300. For example, the photonics package 400 and the buffer chip 300 may be arranged in a region surrounded by the plurality of stacked structures 200 and one side of the package substrate 100. For example, when a side surface facing the buffer chip 300 among the side surfaces of the photonics package 400 is a first side surface, a side surface adjacent to the first side surface may face the plurality of stacked structures 200, and a side surface opposite the first side surface may face the outside of the photonics package 400.

The first molding layer 430 may be on the optical integrated circuit chip 410, and may surround the electronic integrated circuit chip 420. An area size of the optical integrated circuit chip 410 may be greater than an area size of the electronic integrated circuit chip 420. The first molding layer 430 may fill a portion of an upper portion of the optical integrated circuit chip 410 where the electronic integrated circuit chip 420 is not stacked. Hereinafter, the area size may refer to a horizontal area size, such as an area size of a surface parallel to the X-Y plane.

In one embodiment, the first molding layer 430 may include or be formed of epoxy resin, polyimide resin, etc. The first molding layer 430 may include or be formed of, for example, epoxy molding compound (EMC).

In one embodiment, external sidewalls of the first molding layer 430 may be coplanar with external sidewalls of the optical integrated circuit chip 410. An upper surface 430_U (e.g., top surface) of the first molding layer 430 may be coplanar with an upper surface 420_U (e.g., top surface) of the electronic integrated circuit chip 420. For example, a vertical level of the upper surface 430_U of the first molding layer 430 may be the same as a vertical level of an upper surface 420_U of the electronic integrated circuit chip 420. For example, the upper surface of the electronic integrated circuit chip 420 may be exposed to the outside of the semiconductor package 1000. Accordingly, the semiconductor package 1000 may easily dissipate heat generated by the electronic integrated circuit chip 420 to the outside.

The first molding layer 430 may further include an opening portion 430_G. The opening portion 430_G may extend from the upper surface of the first molding layer 430 to the inside. The opening portion 430_G may be above a portion of the waveguide 413. The opening portion 430_G may be on the waveguide 413, and a portion of the waveguide 413 may be exposed to the outside through the opening portion 430_G.

For example, a first portion of the upper portion wiring insulating layer 4122a that covers the top of waveguide 413 may be transparent, and the opening portion 430_G may be located on the first portion of the upper portion wiring the insulating layer 4122a, so that a portion of the waveguide 413 may be exposed to the outside through the opening portion 430_G and the first portion of the upper portion wiring the insulating layer 4122a

For example, though not shown, a part of waveguide 413 may extend vertically within the upper portion wiring insulating layer 4122a to terminate at a top surface of the upper portion wiring insulating layer 4122a and be exposed at the opening portion 430_G.

In some embodiments, the waveguide 413 may further include a grating coupler 413_GC, and the grating coupler 413_GC may be arranged as a portion of the waveguide 413 exposed to the outside by the opening portion 430_G For example, a first portion of the upper portion wiring insulating layer 4122a that covers top of the grating coupler 413_GC may be transparent and be exposed by the opening portion 430_G and a first portion of the upper portion wiring insulating layer 4122a

For example, the grating coupler 413_GC may extend vertically to terminate at a top surface of the upper portion wiring insulating layer 4122a and be exposed at the opening portion 430_G.

In some embodiments, the optical fiber F may be inside the opening portion 430_G of the first molding layer 430. The optical fiber F may on the waveguide 413. For example, the optical fiber F may transceive an optical signal to and from the waveguide 413. The optical fiber F may be optically connected to the waveguide 413 via the grating coupler 413_GC. In some embodiments, the optical fiber F may include an optical fiber array unit (FAU).

In some embodiments, the semiconductor package 1000 may further include a second molding layer 500. The second molding layer 500 may be on the package substrate 100, and may surround the plurality of stacked structures 200, the buffer chip 300, and the photonics package 400. For example, side surfaces of each of the plurality of stacked structures 200, the buffer chip 300, and the photonics package 400 may be covered by the second molding layer 500.

For example, the second molding layer 500 may include or be formed of epoxy resin, polyimide resin, etc. The second molding layer 500 may be, for example, EMC.

In some embodiments, a boundary surface may be between the first molding layer 430 and the second molding layer 500. For example, when a curing time of the first molding layer 430 is different from a curing time of the second molding layer 500, a boundary surface may be formed between the first molding layer 430 and the second molding layer 500. After the first molding layer 430 is cured and an interval has passed, the second molding layer 500 may be cured and a boundary surface may be formed between the first molding layer 430 and the second molding layer 500.

In some embodiments, an area size of the second molding layer 500 may be the same as an area size of the package substrate 100. For example, external sidewalls of the second molding layer 500 may be coplanar with external sidewalls of the package substrate 100.

In some embodiments, an upper surface 500_U (e.g., top surface) of the second molding layer 500 may be coplanar with an upper surface 300_U (e.g., top surface) of the buffer chip 300. For example, a vertical level of the upper surface 500_U of the second molding layer 500 may be the same as a vertical level of the upper surface 300_U of the buffer chip 300. The upper surface 300_U of the buffer chip 300 may be exposed to the outside of the semiconductor package 1000. Accordingly, the semiconductor package 1000 may easily dissipate heat generated by the buffer chip 300 to the outside.

In some embodiments, the upper surface 430_U (e.g., top surface) of the first molding layer 430, the upper surface 420_U (e.g., top surface) of the electronic integrated circuit chip 420, the upper surface 500_U (e.g., top surface) of the second molding layer 500, and the upper surface 300_U (e.g., top surface) of the buffer chip 300 may be coplanar with each other.

The semiconductor package 1000 may transceive wide bandwidth by using the photonics package 400, and thus, the data transmission speed may be improved. In addition, because one buffer chip 300 may control the plurality of stacked structures 200, the size of the semiconductor package 1000 may be relatively reduced and the data processing speed may be improved.

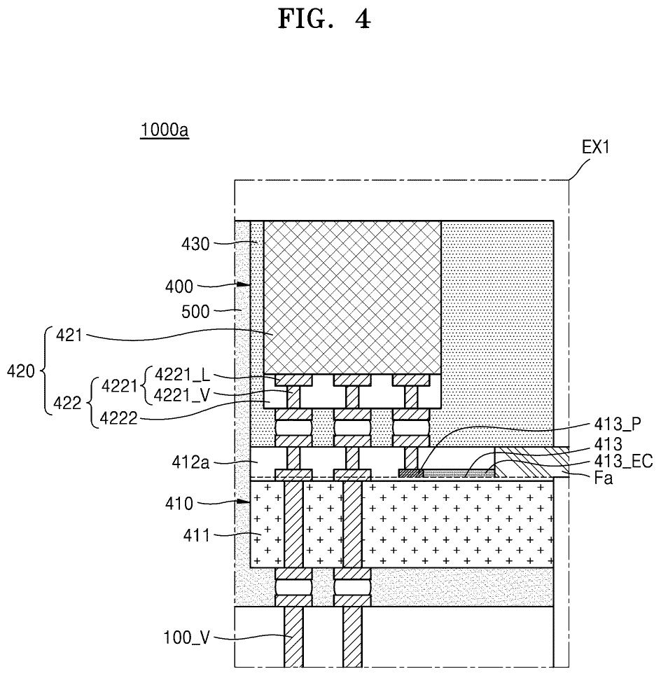

FIG. 4 is a schematic enlarged cross-sectional view of a portion of a semiconductor package 1000a, according to an embodiment.

Most of components constituting the semiconductor package 1000a and materials constituting the components to be described below may be substantially the same as or similar to those described above with reference to FIG. 3. Accordingly, for convenience of descriptions, differences between the semiconductor package 1000a of FIG. 4 and the semiconductor package 1000 of FIG. 3 described above are mainly described.

The photonics package 400 may include the optical integrated circuit chip 410, the electronic integrated circuit chip 420, and the first molding layer 430. In some embodiments, the photonics package 400 may include a V-groove recessed inward from the side surface of the V-groove. For example, the V-groove may be in a first distribution structure 412a of the optical integrated circuit chip 410. However, the embodiment is not limited thereto, and depending on the depth of the V-groove in the vertical direction (Z direction), the V-groove may be in the first molding layer 430 and the first distribution structure 412a.

An optical fiber Fa may be optically connected to the photonics package 400 via an edge coupler 413_EC. For example, the optical fiber Fa may be inside the V-groove of the photonics package 400, and vertical levels of the waveguide 413 and at least portions of the optical fiber Fa may be substantially the same. The optical fiber Fa and the optical integrated circuit chip 410 may be optically connected to each other via the edge coupler 413_EC, and may transceive optical signals of multi-frequencies to and from each other.

In some embodiments, a first side surface of the photonics package 400 may be coplanar with the side surface of the package substrate 100. For example, the V-groove of the photonics package 400 may be recessed inward from the first side surface of the V-groove. In this example, neither the plurality of stacked structures 200 nor the second molding layer 500 are on a side portion at a first side surface of the photonics package 400.

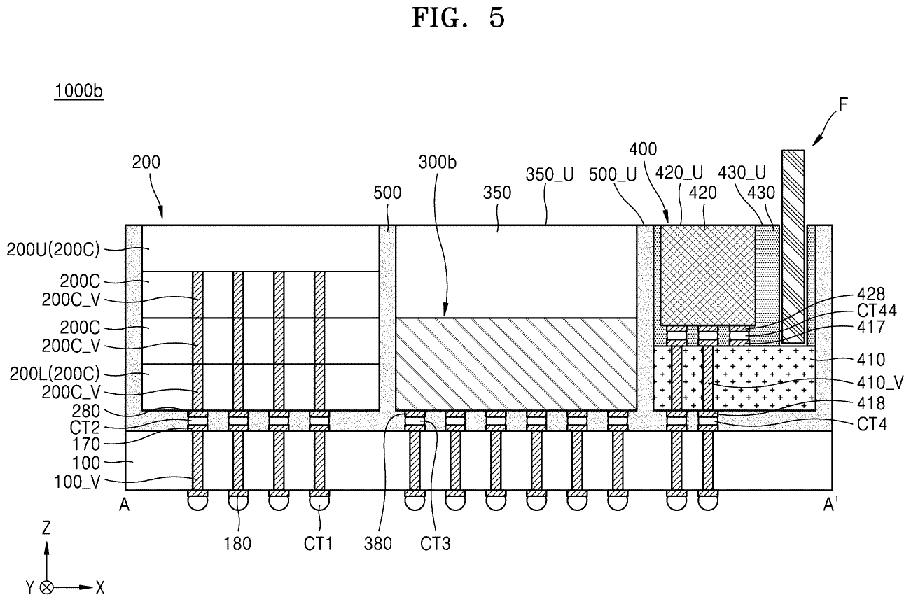

FIG. 5 is a schematic cross-sectional view of a semiconductor package 1000b, according to an embodiment.

Most of components constituting the semiconductor package 1000b and materials constituting the components to be described below may be substantially the same as or similar to those described above with reference to FIG. 2. Accordingly, for convenience of descriptions, differences between the semiconductor package 1000b of FIG. 5 and the semiconductor package 1000 of FIG. 2 described above are mainly described.

The semiconductor package 1000b may further include a dummy chip 350. The dummy chip 350 may be on a buffer chip 300b. The dummy chip 350 may include, for example, a semiconductor material such as Si. In some embodiments, the dummy chip 350 may include only a semiconductor material. For example, the dummy chip 350 may include a portion of a bare wafer without any devices or other layers formed therein.

In some embodiments, a height of the buffer chip 300b may be different from a height of the photonics package 400. In some embodiments, the height of the buffer chip 300b may be less than the height of the photonics package 400. A vertical level of an upper surface of the buffer chip 300b may be lower than a vertical level of the upper surface of the photonics package 400, and may be higher than a vertical level of a lower surface of the photonics package 400.

The sum of heights of the dummy chip 350 and the buffer chip 300b may be the same as the height of the photonics package 400. When there is a height difference between the buffer chip 300b and the photonics package 400, the dummy chip 350 may prevent the second molding layer 500 from covering the upper surface of the buffer chip 300b to help dissipating heat generated by the buffer chip 300b.

In some embodiments, an upper surface 350_U of the dummy chip 350 may be a coplanar surface with the upper surface 500_U of the second molding layer 500. For example, a vertical level of the upper surface 350_U of the dummy chip 350 may be the same as a vertical level of the upper surface 500_U of the second molding layer 500. For example, the upper surface 350_U of the dummy chip 350 may be a coplanar surface with the upper surface 420_U of the electronic integrated circuit chip 420 and the upper surface 430_U of the first molding layer 430. In this embodiment, the upper surface 350_U of the dummy chip 350 and the upper surface 430_U of the electronic integrated circuit chip 420 are not covered by the second molding layer 500 and the first molding layer 430, respectively, and may be open to the outside of the semiconductor package 1000b.

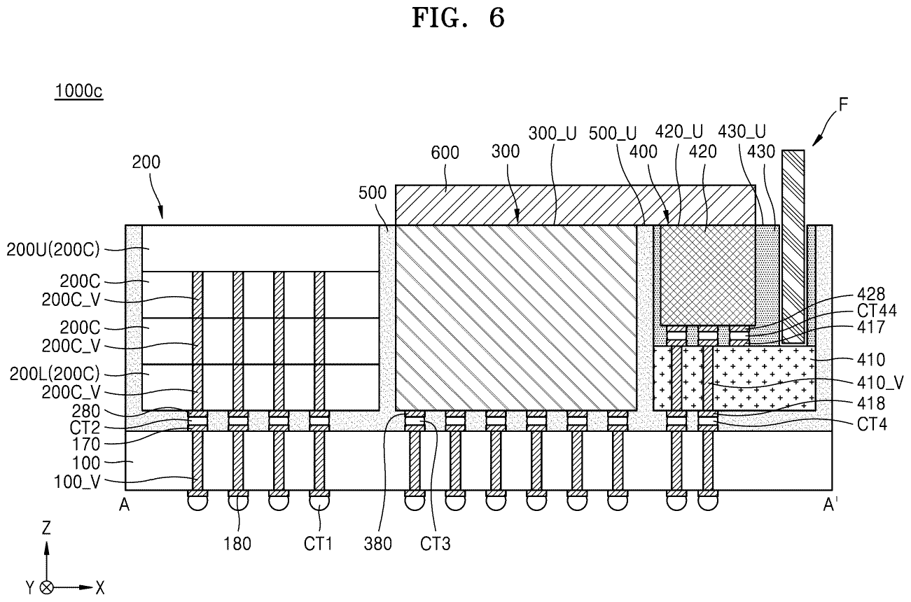

FIG. 6 is a schematic cross-sectional view of a semiconductor package 1000c, according to an embodiment.

Most of components constituting the semiconductor package 1000c and materials constituting the components to be described below may be substantially the same as or similar to those described above with reference to FIG. 2. Accordingly, for convenience of descriptions, differences between the semiconductor package 1000c of FIG. 6 and the semiconductor package 1000 of FIG. 2 described above are mainly described.

The semiconductor package 1000c may further include a heat sink 600. The heat sink 600 may be on the buffer chip 300. In some embodiments, when a dummy chip (refer to 350 in FIG. 5) is on the buffer chip 300, the heat sink 600 may be on the dummy chip. In some embodiments, the heat sink 600 may be in contact with the upper surface of the buffer chip 300 and an upper surface of the electronic integrated circuit chip 420.

The heat sink 600 may be configured to dissipate heat generated by the buffer chip 300 and/or the electronic integrated circuit chip 420. The heat sink 600 may include or be formed of a heat conductive material having high thermal conductivity. For example, the heat sink 600 may include or be formed of a metal, such as Cu and Al, or a carbon-containing material, such as graphene, graphite, and/or carbon nanotube. However, the material of the heat sink 600 is not limited thereto. In some embodiments, the heat sink 600 may include or consist of a single metal layer or a plurality of stacked metal layers.

In some embodiments, the heat sink 600 may be attached onto the buffer chip 300 by using a thermal interface material (TIM). The TIM may directly connect to the heat sink 600 and the buffer chip 300. As the heat sink 600 is in thermal communication with the buffer chip 300 by using the TIM layer, heat dissipation characteristics may be improved.

The TIM layer may include or be formed of a material which is thermally conductive and electrically insulating. For example, the TIM layer may include or be formed of a polymer including a metal particle of Au or Cu, thermal grease, white grease, or a combination thereof.

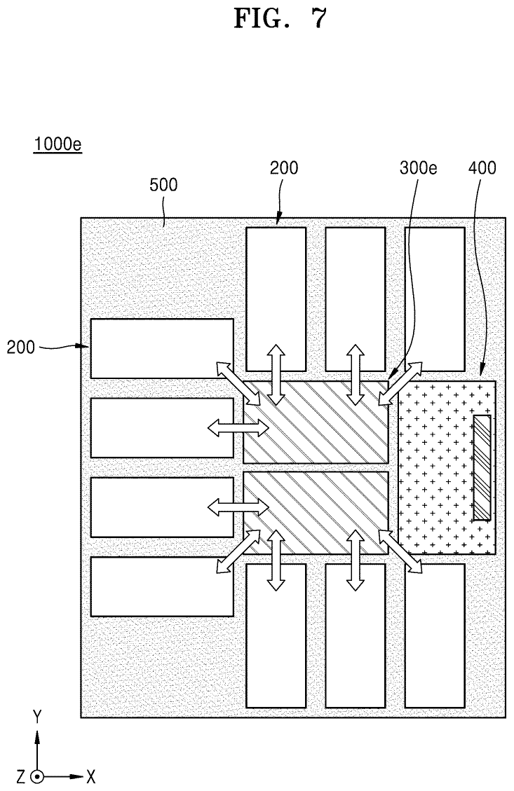

FIG. 7 is a schematic plan view of a semiconductor package 1000e according to an embodiment.

Most of components constituting the semiconductor package 1000e and materials constituting the components to be described below may be substantially the same as or similar to those described above with reference to FIG. 1. Accordingly, for convenience of descriptions, differences between the semiconductor package 1000e of FIG. 7 and the semiconductor package 1000 of FIG. 1 described above are mainly described.

The semiconductor package 1000e may include a plurality of buffer chips 300e. The plurality of buffer chips 300e may be apart from each other in the horizontal direction. For example, the second molding layer 500 may be between the plurality of buffer chips 300e. In some embodiments, the plurality of stacked structures 200 may be arranged to surround three sides of the total area occupied by the plurality of buffer chips 300e.

The number of plurality of buffer chips 300e may be less than the number of plurality of stacked structures 200. For example, each of the plurality of buffer chips 300e may be electrically connected to at least two stacked structures 200. In some embodiments, a group of two or more of the plurality of stacked structures 200 may be electrically connected to each one of the plurality of buffer chips 300c.

In some embodiments, the plurality of buffer chips 300e may be electrically connected to one photonics package 400. However, the embodiment is not limited thereto, and the semiconductor package 1000e may include a plurality of photonics packages 400, and the plurality of buffer chips 300e may be electrically connected to different photonics packages 400.

In the semiconductor package 1000e, the number of stacked structures 200 controlled by each of the plurality of buffer chips 300e may be decreased, and the size of one buffer chip 300e may be decreased. Accordingly, the yield of the buffer chip 300 may be increased, and the unit production cost of the semiconductor package 1000e may be reduced.

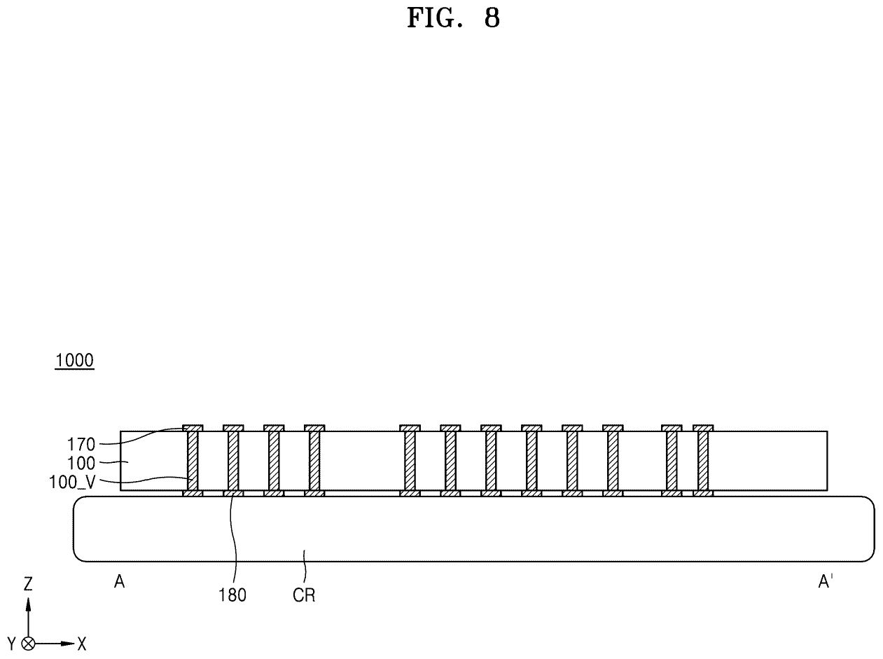

FIGS. 8 through 11 are diagrams illustrating a manufacturing method of a semiconductor package 1000, according to example embodiments.

FIGS. 8 to 11 are cross-sectional views of the semiconductor package 1000 of FIG. 1 taken along line A-A′in FIG. 1 according to the order of the manufacturing process of the semiconductor package 1000.

Most of components constituting the semiconductor package 1000 and materials constituting the components to be described below may be substantially the same as or similar to those described above with reference to FIG. 1. Accordingly, for convenience of descriptions, duplicate descriptions of the semiconductor package 1000 of FIG. 1 are omitted.

Referring to FIG. 8, the package substrate 100 may be attached to a carrier substrate CR by using an adhesive insulating layer (not illustrated).

The carrier substrate CR may include or be, for example, glass, Si, or aluminum oxide. The adhesive insulating layer may include or be an arbitrary material capable of fixing the package substrate 100. The adhesive insulating layer may include or be an adhesive tape in which, for example, an adhesion force is weakened by heat treatment or an adhesion force is weakened by laser irradiation.

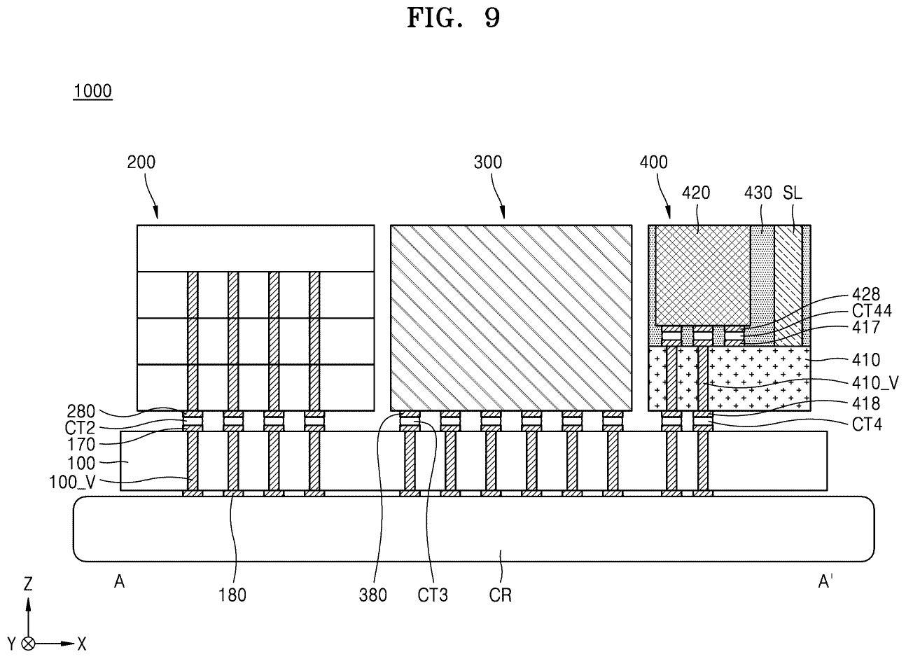

Referring to FIG. 9, the plurality of stacked structures 200, the buffer chip 300, and the photonics package 400 may be attached to the package substrate 100.

For example, the plurality of stacked structures 200 may be referred to as an HBM core, and the buffer chip 300 may be referred to as an HBM controller die or an interfacing chip. The buffer chip 300 may be apart from the plurality of stacked structures 200 in the horizontal direction, but may be electrically connected to the plurality of stacked structures 200 by using the package substrate 100. Accordingly, one buffer chip 300 may control the plurality of stacked structures 200.

The photonics package 400 may be on one side of the buffer chip 300. The photonics package 400 may be near a first side surface of the buffer chip 300, and the side surfaces except for the first side surface of the buffer chip 300 may face the plurality of stacked structures 200. In one embodiment, the photonics package 400 may be electrically connected to the PHY of the buffer chip 300.

In the process of forming the first molding layer 430 of the photonics package 400, after the first molding layer 430 is formed to cover the electronic integrated circuit chip 420 on the optical integrated circuit chip 410, a portion of the upper portion of the first molding layer 430 may be removed. For example, the upper portion of the first molding layer 430 may be ground so that the upper surface of the electronic integrated circuit chip 420 is exposed. Accordingly, the upper surface 420_U of the electronic integrated circuit chip 420 and the upper surface 430_U of the first molding layer 430 may be coplanar with each other.

The first molding layer 430 of the photonics package 400 may include a sacrificial layer SL. For example, the sacrificial layer SL may penetrate the first molding layer 430, and may be on the waveguide 413 of the optical integrated circuit chip 410.

The plurality of stacked structures 200, the buffer chip 300, and the photonics package 400 may be electrically connected to the package substrate 100 by using connection terminals. For example, the connection terminals may include solder balls or solder bumps.

However, the embodiments are not limited thereto, and the plurality of stacked structures 200, the buffer chip 300, and the photonics package 400 may be electrically connected to the package substrate 100 by using an ACF, an NCF, direct bonding, or hybrid bonding.

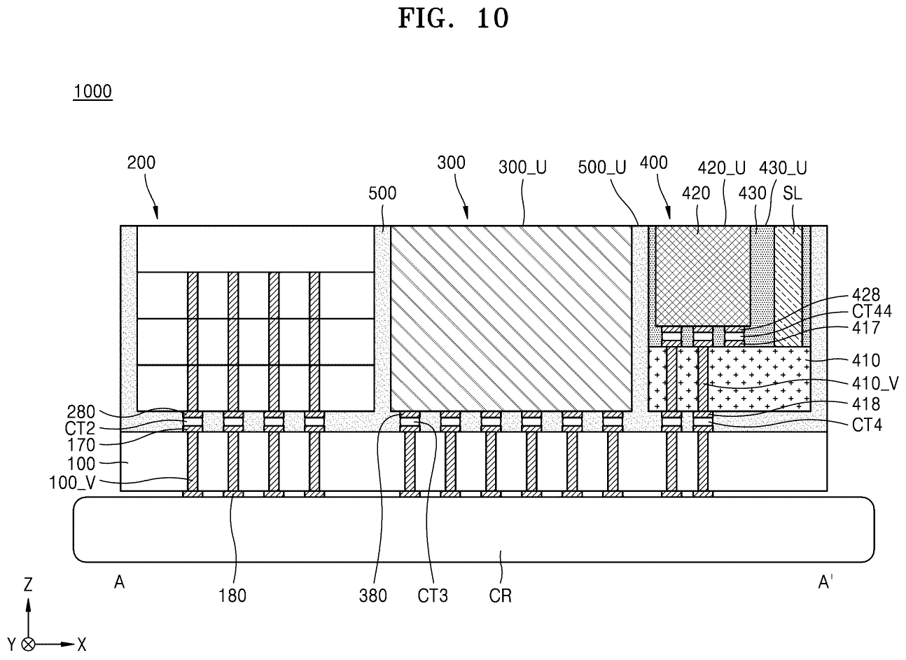

Referring to FIG. 10, the second molding layer 500 may be formed, on the package substrate 100, to surround the plurality of stacked structures 200, the buffer chip 300, and the photonics package 400.

After the second molding layer 500 is formed to cover the plurality of stacked structures 200, the buffer chip 300, and the photonics package 400, a portion of an upper portion of the second molding layer 500 may be removed. For example, the upper portion of the second molding layer 500 may be ground so that the upper surface of the buffer chip 300 is exposed. Accordingly, the upper surface 300_U of the buffer chip 300 may be coplanar with the upper surface 500_U of the second molding layer 500.

In some embodiments, when the upper surface 300_U of the buffer chip 300 is coplanar with an upper surface of the photonics package 400, the upper surface of the photonics package 400, including the upper surface 420_U of the electronic integrated circuit chip 420 and the upper surface 430_U of the first molding layer 430, may be exposed to the outside of the semiconductor package 1000. For example, the upper surface 300_U of the buffer chip 300, the upper surface 500_U of the second molding layer 500, the upper surface 420_U of the electronic integrated circuit chip 420, and the upper surface 430_U of the first molding layer 430 may be coplanar with each other.

The first molding layer 430 and the second molding layer 500 may have different curing times. Accordingly, even when constituent materials of the first molding layer 430 and the second molding layer 500 are the same, a boundary surface may be formed between the first molding layer 430 and the second molding layer 500.

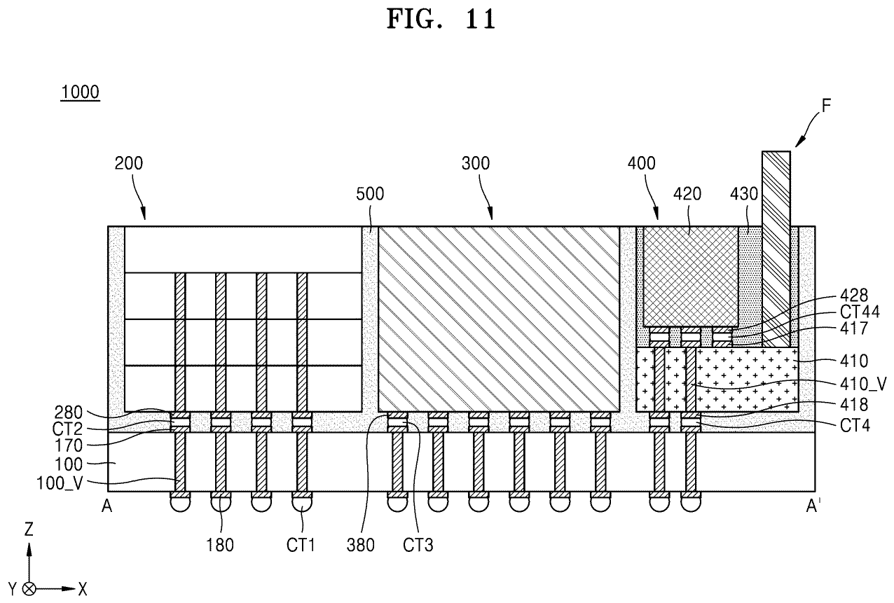

Referring to FIG. 11, the sacrificial layer SL may be removed, and the optical fiber F may be attached to the photonics package 400.

By removing the sacrificial layer SL, an opening portion may be formed in the first molding layer 430. Accordingly, a portion of the waveguide 413 of the optical integrated circuit chip 410 may be exposed to the outside. The optical fiber F may be attached inside the opening portion of the first molding layer 430. One end portion of the optical fiber F may face the optical integrated circuit chip 410, and may be optically connected to the waveguide 413 of the optical integrated circuit chip 410.

After the carrier substrate CR is removed, the external connection terminals CT1 may be attached to the lower pad 180 of the package substrate 100. In some embodiments, the external connection terminals CT1 may include, for example, solder balls, conductive bumps, ball grid arrays (BGAs), or a combination thereof.

While the inventive concept has been particularly shown and described with reference to embodiments thereof, it will be understood that various changes in form and details may be made therein without departing from the spirit and scope of the following claims.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Components described as thermally connected or in thermal communication are arranged such that heat will follow a path between the components to allow the heat to transfer from the first component to the second component. Simply because two components are part of the same device or package does not make them thermally connected. In general, components which are heat-conductive and directly connected to other heat-conductive or heat-generating components (or connected to those components through intermediate heat-conductive components or in such close proximity as to permit a substantial transfer of heat) will be described as thermally connected to those components, or in thermal communication with those components. On the contrary, two components with heat-insulative materials therebetween, which materials significantly prevent heat transfer between the two components, or only allow for incidental heat transfer, are not described as thermally connected or in thermal communication with each other. The terms “heat-conductive” or “thermally-conductive” do not apply to a particular material simply because it provides incidental heat conduction, but are intended to refer to materials that are typically known as good heat conductors or known to have utility for transferring heat, or components having similar heat conducting properties as those materials.

What is claimed is:

1. A semiconductor package comprising:
a package substrate;
a plurality of stacked structures on the package substrate, each stacked structure including a plurality of core chips stacked on each other, each core chip including a memory cell array including a plurality of memory cells;
a buffer chip on the package substrate and spaced apart from the plurality of stacked structures in a horizontal direction; and
a photonics package including an optical integrated circuit chip on the package substrate, an electronic integrated circuit chip on the optical integrated circuit chip, and a first molding layer surrounding side surfaces of the electronic integrated circuit chip,
wherein the buffer chip is configured to control the memory cells of the core chips of each of the plurality of stacked structures.

2. The semiconductor package of claim 1, wherein the plurality of core chips each include dynamic random access memory (RAM) (DRAM) memory cells.

3. The semiconductor package of claim 1, wherein:
the package substrate is configured to transfer an electrical signal converted from the photonics package to the buffer chip, and
the package substrate is configured to transfer electrical signals output by the plurality of stacked structures to the buffer chip.

4. The semiconductor package of claim 1, wherein:
the photonics package is electrically connected to a physical layer of the buffer chip via the package substrate, and
the plurality of stacked structures are electrically connected to the buffer chip via the package substrate.

5. The semiconductor package of claim 1, further comprising a second molding layer on the package substrate and surrounding side surfaces of the plurality of stacked structures, the buffer chip, and the photonics package.

6. The semiconductor package of claim 5, further comprising a boundary surface between the first molding layer and the second molding layer.

7. The semiconductor package of claim 1, wherein a top surface of the buffer chip is at the same vertical level above a bottom surface of the package substrate as a top surface of the photonics package.

8. The semiconductor package of claim 1,
wherein the optical integrated circuit chip further comprises a plurality of through vias and a waveguide, and
the waveguide is at an upper surface of the optical integrated circuit chip.

9. The semiconductor package of claim 8,
wherein the first molding layer of the photonics package further comprises an opening portion extending from an upper surface of the first molding layer inward, and
the opening portion of the first molding layer is above a portion of the waveguide of the optical integrated circuit chip.

10. The semiconductor package of claim 1, further comprising a dummy chip on the buffer chip.

11. The semiconductor package of claim 10, wherein a top surface of the dummy chip at the same vertical level above a bottom surface of the package substrate as a top surface of the photonics package.

12. The semiconductor package of claim 1, further comprising a heat sink on an upper portion of the buffer chip.

13. A semiconductor package comprising:
a package substrate;
a plurality of stacked structures on the package substrate, each stacked structure including a plurality of core chips stacked on each other, each core chip including a memory cell array including a plurality of memory cells;
a buffer chip on the package substrate and spaced apart from the plurality of stacked structures in a horizontal direction; and
a photonics package including an optical integrated circuit chip on the package substrate, an electronic integrated circuit chip on the optical integrated circuit chip, and a first molding layer surrounding side surfaces of the electronic integrated circuit chip,
wherein the buffer chip is configured to control the memory cells of the core chips of each of the plurality of stacked structures,
wherein the total number of buffer chips on the package substrate is less than the total number of stacked structures including the plurality of core chips stacked on each other on the package substrate, and
wherein the plurality of stacked structures and the photonics package are arranged to surround side surfaces of the buffer chip.

14. The semiconductor package of claim 13,
wherein the buffer chip is in a center region of the package substrate, and
the plurality of stacked structures and the photonics package are on a periphery region of the package substrate.

15. The semiconductor package of claim 13,
wherein one side surface among the side surfaces of the buffer chip faces the photonics package, and
the remaining side surfaces among the side surfaces of the buffer chip face the plurality of stacked structures.

16. The semiconductor package of claim 13, wherein:
a first side surface of the photonics package faces the buffer chip, and
at least one of the plurality of stacked structures faces a second side surface adjacent to the first side surface of the photonics package.

17. The semiconductor package of claim 13, comprising at least one additional buffer chip.

18. A semiconductor package comprising:
a package substrate;
a plurality of stacked structures on the package substrate, each stacked structure including a plurality of core chips stacked on each other, each core chip including dynamic random access memory (RAM) (DRAM) memory cells;
a buffer chip on the package substrate and spaced apart from the plurality of stacked structures;
a photonics package including an optical integrated circuit chip on the package substrate, an electronic integrated circuit chip on the optical integrated circuit chip, and a first molding layer surrounding side surfaces of the electronic integrated circuit chip; and
a second molding layer on the package substrate and surrounding side surfaces of the plurality of stacked structures, the buffer chip, and the photonics package,
wherein the buffer chip is configured to control the memory cells of the core chips of each of the plurality of stacked structures,
wherein the plurality of stacked structures and the photonics package are arranged to surround side surfaces of the buffer chip, and
wherein the first molding layer of the photonics package comprises an opening portion extending from an upper surface of the first molding layer inward.

19. The semiconductor package of claim 18,
wherein a top surface of the first molding layer and a top surface of the second molding layer are coplanar surfaces with each other, and
wherein a boundary surface is between the first molding layer and the second molding layer.

20. The semiconductor package of claim 18,
wherein a first side surface among the side surfaces of the buffer chip faces the photonics package, and
remaining side surfaces among the side surfaces of the buffer chip face the plurality of stacked structures.
